(19) United States
(12) Patent Application Publication
(10) Pub. No.: US 2007/0278498 A1
(43) Pub. Date: Dec. 6, 2007

(54) LIGHT EMITTING DEVICE, ELECTRONIC APPARATUS, AND MANUFACTURING METHOD OF LIGHT EMITTING DEVICE

(75) Inventors: Yasuo Nakamura, Tokyo (JP); Yoshifumi Tanada, Atsugi (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/754,505

(22) Filed: May 29, 2007

(30) Foreign Application Priority Data
Jun. 2, 2006 (JP) 2006-155466

(51) Int. Cl. H01L 33/00

(52) U.S. Cl. 257/79

(57) ABSTRACT

A light emitting device including a thin film transistor and an inorganic EL element, and a manufacturing method thereof. The present invention provides a manufacturing method of a light emitting device, including a step of forming a light emitting layer including at least a layer made from an inorganic fluorescent material over a first electrode while heating a substrate provided with the first electrode at a temperature in the range of 100 to 1200° C., preferably 200 to 800° C., and a step of forming a second electrode and a thin film transistor after the light emitting layer is formed.

### BACKGROUND OF THE INVENTION

1. Field of the Invention

The present invention relates to a light emitting device and an electronic apparatus each having a light emitting element utilizing electroluminescence.

2. Description of the Related Art

In recent years, flat and thin display devices have been needed as display devices in a television, a cellular phone, a digital camera, and the like. As the display devices satisfying this need, display devices utilizing self-light emitting elements have attracted attention. One of the self-light emitting elements is a light emitting element utilizing electroluminescence (EL), and this light emitting element includes a light emitting material interposed between a pair of electrodes and can provide light emission from the light emitting material by voltage application.

Such a self-light emitting element has advantages over a liquid crystal display, such as high visibility of pixels and no backlight required, and is considered suitable for a flat panel display element. Another major advantage of such a light emitting element is that it can be manufactured to be thin and lightweight. In addition, extremely high response speed is also a feature thereof.

Further, such a self-light emitting element can be formed into a film shape; therefore, plane light emission can be easily obtained by forming a large-area element. Since this feature is hard to obtain from a point light source typified by an incandescent lamp or an LED, or a linear light source typified by a fluorescent lamp, the self-light emitting element has high utility value as a plane light source which is applicable to a lighting system and the like.

Light emitting elements utilizing electroluminescence are classified depending on whether a light emitting material is an organic compound or an inorganic compound. In general, the former is called an organic EL element and the latter is called an inorganic EL element.

An inorganic fluorescent material extremely changes its luminous efficiency depending on its crystal state. Even a material used for an inorganic EL light emitting layer is no exception, of which it is known that a film having high crystallinity can provide luminescence at a higher efficiency than a film having low crystallinity.

Further, the luminous efficiency also depends on the crystal system. In the case of zinc sulfide, it is known that a cubic crystal film can provide luminescence at a higher efficiency than a hexagonal crystal film (see Reference 1: Japanese Published Patent Application No. 2005-336275).

As a method of obtaining a film having a desired crystal state, there is a method of forming a film while heating a substrate. In the case of zinc sulfide, by forming a film thereof while heating a substrate at least at 100° C. or more, a cubic crystal film exhibiting a high luminous efficiency can be formed.

Further, although a defect in inorganic fluorescent material crystals causes a decline in luminous efficiency, a crystal defect existing in a light emitting layer can be repaired and crystal growth can be promoted by performing thermal treatment at a high temperature of 400° C. after film formation of the light emitting layer.

Further, in the case where a light emitting element is applied to a display, an active matrix display, in which a lighting period of each pixel is hardly affected by the total number of pixels in the display compared with a passive matrix display, can display an image at a high luminance even in the case of a large-screen display or a high-definition display where the number of pixels is large.

As examples of an active matrix display using an amorphous silicon TFT or a polysilicon TFT; a liquid crystal display, an organic EL display, and the like can be given. In the case of a liquid crystal display or an organic EL display, a display material thereof has no resistance to a high-temperature process or a wet-etching process. Therefore, a process in which a display element is manufactured over a substrate provided in advance with a TFT is generally adopted.

### SUMMARY OF THE INVENTION

When an active matrix inorganic EL display using an amorphous silicon TFT or a polysilicon TFT is manufactured in a similar order to the conventional one, that is, when an inorganic EL element is manufactured as a light emitting element over a substrate provided in advance with a TFT, the following problems occur.

When after a light emitting layer made from an inorganic fluorescent material is formed over a substrate with an amorphous silicon TFT or a polysilicon TFT, thermal treatment at a high temperature of 500° C. or more is performed to the whole substrate in order to increase the luminous efficiency, defect increase due to hydrogen elimination from amorphous silicon or polysilicon damages TFT properties.

Further, there is limitation on usable materials; for example, a low-melting-point wiring material such as aluminum cannot be used, and an organic material cannot be used for a planarization film or the like.

In view of the foregoing problems, it is an object of the present invention to provide a light emitting device including a thin film transistor and an inorganic EL element. In addition, it is another object of the present invention to provide a manufacturing method thereof.

An inorganic EL material can have enough resistance to a temperature of approximately 750° C. that is the highest temperature of a TFT manufacturing process, unlike a liquid crystal material or an organic EL material. The present inventors therefore have found that by employing a method in which a TFT is manufactured after a first electrode and a light emitting layer including at least a layer made from an inorganic fluorescent material are formed over a substrate prior to a TFT manufacturing process, an inorganic EL light emitting element including a TFT can be manufactured without subjecting the TFT to thermal treatment at 500° C. or more for increasing luminous efficiency of a light emitting layer.

Therefore, one feature of the present invention is a light emitting device in which an inorganic EL element and a thin film transistor are formed over a substrate and the inorganic EL element is provided so as to be nearer to the substrate than the thin film transistor.

In the above-described structure, it is preferable that the inorganic EL element include a first electrode (also referred to as a first electrode layer), a second electrode (also referred to as a second electrode layer), and a light emitting layer including at least a layer made from an inorganic fluorescent material and a planarization film having contact holes for drawing the first and second electrodes be provided over the light emitting layer, the first electrode, and the second electrode.

Note that, a light emitting device in this specification includes an image display device, a light emitting device, or a light source (including a lighting installation). Further, the following are all included in a light emitting device: a module in which a connector such as an FPC (Flexible Printed Circuit), a TAB (Tape Automated Bonding) tape, or a TCP (Tape Carrier Package) is attached to a panel provided with a light emitting element; a module provided with a printed wiring board at the tip of the TAB tape or the TCP; and a module in which an IC (Integrated Circuit) is directly mounted onto a light emitting element by a COG (Chip On Glass) method.

Further, an electronic apparatus in which a light emitting element of the present invention is used for a display portion is also included in the scope of the present invention. Therefore, one feature of the electronic apparatus of the present invention is to include a display portion, and to include the above-described light emitting device in the display portion.

Further, one feature of the present invention is a manufacturing method of a light emitting device, including a step of forming a light emitting layer including at least a layer made from an inorganic fluorescent material over a first electrode while heating a substrate provided with the first electrode at a temperature in the range of room temperature to 1200° C., preferably 100 to 800° C., and a step of forming a second electrode and a thin film transistor after the light emitting layer is formed.

Further, one feature of the present invention is a manufacturing method of a light emitting device, including a step of forming a light emitting layer including at least a layer made from an inorganic fluorescent material over a first electrode, a step of performing thermal treatment at a temperature in the range of 300 to 1500° C., preferably 450 to 1200° C. after the light emitting layer is formed, and a step of forming a second electrode and a thin film transistor after the thermal treatment.

In the above-described structure, the thermal treatment is preferably performed immediately after the step of forming the light emitting layer.

A light emitting device of the present invention, which includes a thin film transistor (TFT) and an inorganic EL element, can be applied to an active matrix light emitting device.

Further, since defect increase due to hydrogen elimination from amorphous silicon, polysilicon, or the like used in the thin film transistor does not occur, an active matrix inorganic EL display can be manufactured without damaging the TFT properties. Further, an electronic apparatus including an active matrix inorganic EL display can be manufactured.

Further, even a low-melting-point material such as aluminum or a low-heat-resistance organic material can be used for a TFT of an inorganic EL display. That is, the range of usable materials is increased.

### BRIEF DESCRIPTION OF THE DRAWINGS

FIGS. 1A and 1B are diagrams showing a light emitting device of the present invention.

FIGS. 2A to 2D are diagrams showing a light emitting device of the present invention.

FIGS. 3A to 3C are diagrams showing a light emitting device of the present invention.

FIGS. 4A and 4B are diagrams showing a light emitting device of the present invention.

FIG. 5 is a diagram showing a light emitting device of the present invention.

FIGS. 6A and 6B are diagrams each showing a light emitting device of the present invention.

FIGS. 7A to 7D are diagrams each showing an electronic apparatus of the present invention.

FIG. 8 is a diagram showing an electronic apparatus of the present invention.

FIG. 9 is a diagram showing an electronic apparatus of the present invention.

### DETAILED DESCRIPTION OF THE INVENTION

Although the present invention will be fully described by way of embodiment modes with reference to the accompanying drawings, it is to be understood that various changes and modifications will be apparent to those skilled in the art. Therefore, unless such changes and modifications depart from the spirit and scope of the present invention, they should be construed as being included therein. In each structure of the present invention described hereinafter, the same reference numerals denote the same portions or portions having similar functions in the drawings, and description thereof is not repeated.

### Embodiment Mode 1

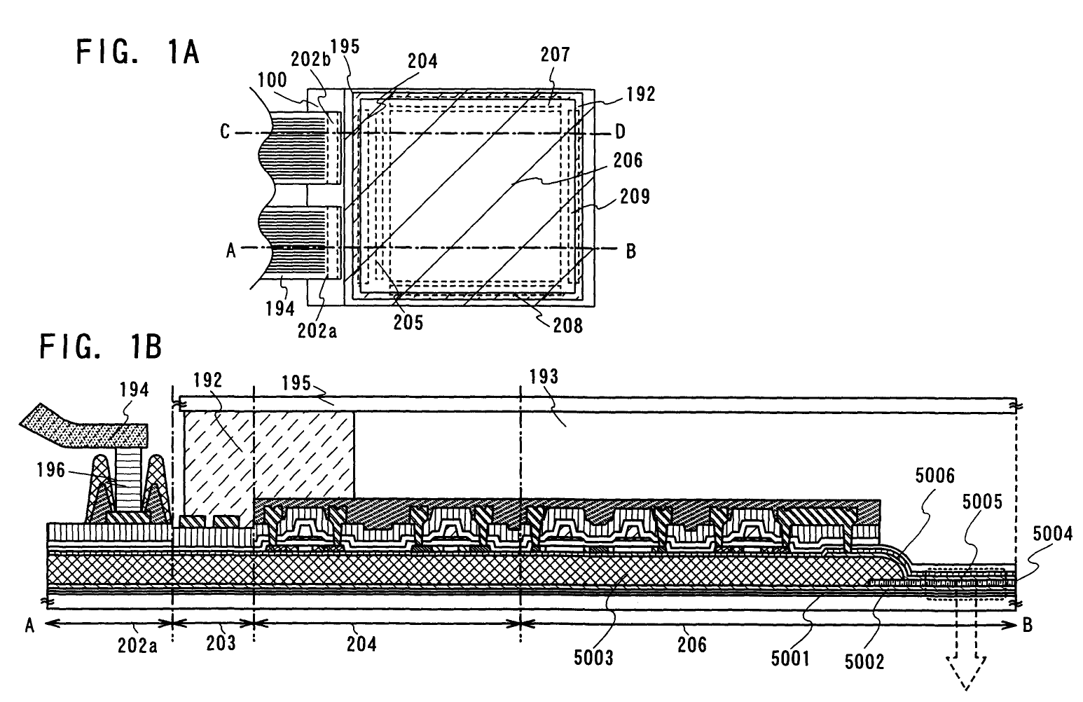

A light emitting device including a TFT and an inorganic EL element and a manufacturing method thereof are described in detail using FIGS. 1A and 1B, 2A to 2D, 3A to 3C, 4A and 4B, 5, and 6A and 6B. FIGS. 1A and 1B are the drawings showing one mode of a light emitting device of the present invention. FIG. 1A is a top diagram of the light emitting device of the present invention, and FIG. 1B is a cross-sectional diagram thereof. In a region along a line A-B in FIG. 1A, an FPC 194 and a wiring of a thin film transistor are electrically connected (the region is hereinafter referred to as an external terminal connection region 202a). In a region along a line C-D in FIG. 1A, the FPC 194 and a first electrode layer of a light emitting element are electrically connected (the region is hereinafter referred to as an external terminal connection region 202b). Note that in FIG. 1B, reference numeral 196 denotes an anisotropic conductive film.

A thin film transistor (TFT) includes a semiconductor layer, a gate insulating layer, and a gate electrode layer as its main components, and can additionally include wiring layers connected to source and drain regions formed in the semiconductor layer. As for the structure, a top-gate type in which the semiconductor layer, the gate insulating layer, and the gate electrode layer are provided sequentially over a substrate; a bottom-gate type in which the gate electrode layer, the gate insulating layer, and the semiconductor layer are provided sequentially over a substrate; and the like are typically known. Any of the structures may be applied to the present invention.

As a substrate 100, a glass substrate, a quartz substrate, or a silicon substrate, a metal substrate or a stainless substrate with an insulating film on its surface may be used. In the case where light emitted from a light emitting element is taken out through the substrate, a substrate having a light-transmitting property such as a glass substrate or a quartz substrate is preferable. A glass substrate changes its shape at a temperature higher than 800° C.; therefore, in the case where the temperature of thermal treatment to a light emitting layer including at least a layer made from an inorganic fluorescent material is equal to or higher than 800° C., a quartz substrate or a sapphire substrate is preferably used rather than a glass substrate.

On the other hand, in the case where light emitted from a light emitting element is taken out not from a substrate side but from a side on which a TFT element is formed later, a nontransparent substrate can be used. Specifically, a ceramics substrate made from alumina, silicon nitride, silicon carbide, or the like can be used.

Further, in the case where after a light emitting element including a TFT element is formed over a substrate provided with a peel layer, the light emitting element is separated from the substrate and used, the substrate does not have limitation on a light-transmitting property. Specifically, a substrate of glass, quartz, alumina, silicon nitride, silicon carbide, ceramics, or the like can be used.

As a base film over the substrate 100 having an insulating surface, a base film 101a is formed of a silicon nitride oxide film (SiNO) with a thickness of 10 to 200 nm (preferably 50 to 100 nm), and a base film 101b is formed of a silicon oxynitride film (SiON) with a thickness of 50 to 200 nm (preferably 100 to 150 nm) by sputtering, PVD (Physical Vapor Deposition), CVD (Chemical Vapor Deposition) such as low-pressure CVD (LPCVD) or plasma CVD, or the like.

In this embodiment mode, the base films 101a and 101b are formed by plasma CVD.

The base film can be formed of silicon oxide, silicon nitride, silicon oxynitride, silicon nitride oxide, or the like and employ a single layer structure or a stacked-layer structure including two layers, three layers, or the like. Note that in this specification, silicon oxynitride is a material in which an oxygen composition ratio is higher than a nitrogen composition ratio and can also be called silicon oxide containing nitrogen. Similarly, silicon nitride oxide is a material in which a nitrogen composition ratio is higher than an oxygen composition ratio and can also be called silicon nitride containing oxygen. In this embodiment mode, a silicon nitride oxide film is formed over the substrate with a thickness of 50 nm using as a reaction gas SiH₄, NH₃, N₂O, N₂, and H₂, and a silicon oxynitride film is formed with a thickness of 100 nm using as a reaction gas SiH₄ and N₂O. Further, the thickness of the silicon nitride oxide film may also be 140 nm and the thickness of the silicon oxynitride film may also be 100 nm.

Next, a first electrode layer 5002 is formed. As the first electrode layer 5002, in the case where light emitted from a light emitting element is taken out from a substrate side, a transparent conductive film formed of a conductive material having a light-transmitting property may be used. For example, indium tin oxide (ITO), indium zinc oxide (IZO), indium oxide containing tungsten oxide, indium zinc oxide containing tungsten oxide (hereinafter also called an IWZO), indium oxide containing titanium oxide, indium tin oxide containing titanium oxide, or the like can be used.

The first electrode layer 5002 can be formed by an evaporation method, sputtering, or the like. In the case of using sputtering, a gas containing moisture (water vapor (H₂O)) or H₂ may be used as a gas. In this embodiment mode, as the first electrode layer 5002, an indium zinc oxide film containing silicon oxide and tungsten oxide is formed by sputtering using, as a target, indium zinc oxide containing tungsten oxide into which silicon oxide is added and using a gas containing moisture (H₂O) or H₂.

In this embodiment mode, silicon oxide is added at 10 wt % into indium zinc oxide containing tungsten oxide. The first electrode layer 5002 may be formed with a total thickness in the range of 100 to 800 nm, and the thickness is 185 nm in this embodiment mode.

In this embodiment mode, a gas containing argon (Ar) at 50 sccm, oxygen (O₂) at 1.0 sccm, and an H₂O gas at 0.2 sccm is used for forming the first electrode layer 5002. The gas containing moisture (water vapor (H₂O)) used in the present invention does not mean a gas containing moisture to some extent depending on a manufacturing method, a storage method, or the like, but means a gas containing moisture positively as one main component. As for the H₂O gas, the flow rate is preferably 0.5 sccm or less. The indium zinc oxide film containing silicon oxide and tungsten oxide formed in this embodiment mode is good in processability, and can be etched without leaving a residue by wet etching using weak acid. By using such a film for a pixel electrode of a display device, a highly reliable display device can be manufactured, in which light extraction efficiency of a light emitting element is good and fault due to etching failure of an electrode or the like is suppressed.

Further, in the case where light emitted from a light emitting element is taken out from only a TFT element side, a reflective electrode formed of a multi-layer or a single layer of a metal film which is superior in heat resistance can be used as the first electrode layer 5002.

Further, the first electrode layer may be formed by stacking a first conductive film with a thickness of 20 to 100 nm and a second conductive film with a thickness of 100 to 400 nm.

Each conductive film may be formed of an element selected from tantalum (Ta), tungsten (W), titanium (Ti), molybdenum (Mo), copper (Cu), chromium (Cr), and neodymium (Nb), or an alloy material or a compound material containing the element as its main component.

Further, a semiconductor film typified by a polycrystalline silicon film which is doped with an impurity element such as phosphorus, or an AgPdCu alloy may also be used.

Further, the present invention is not limited to a single layer structure, and a two-layer or a three-layer structure may also be employed.

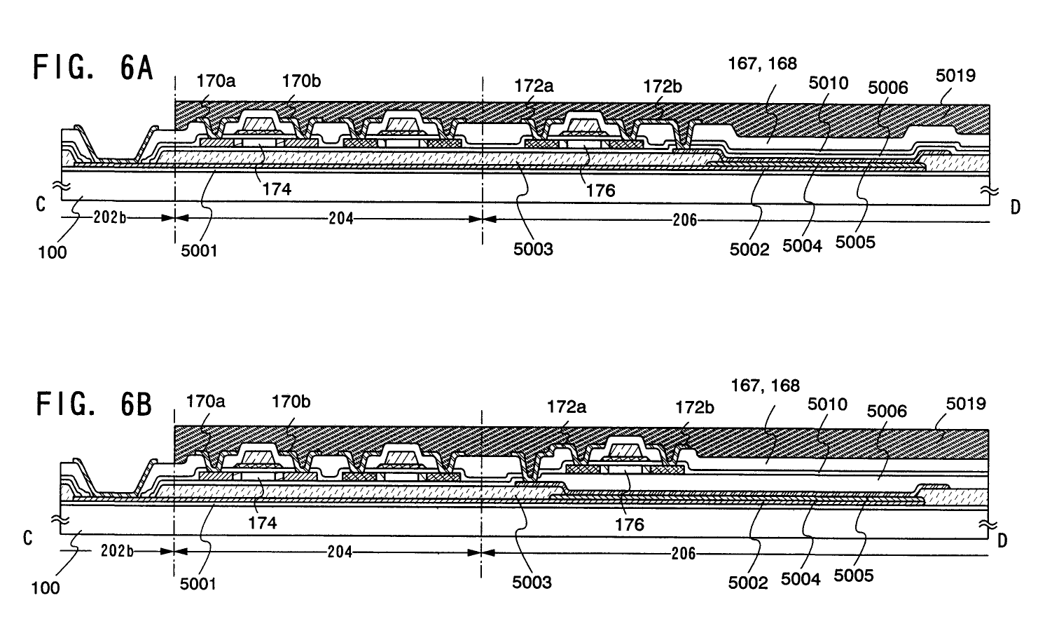

Next, a resist mask may be formed by photolithography to process the first electrode layer 5002 into a desired shape (see FIG. 6A).

The first electrode layer 5002 can be etched into a desired tapered shape by using an ICP (Inductively Coupled Plasma) etching method and appropriately controlling the etching condition (e.g., the amount of electric power applied to a coiled electrode layer, the amount of electric power applied to an electrode layer on the substrate side, or the electrode temperature on the substrate side). As an etching gas, a chlorinated gas such as Cl₂, BCl₃, SiCl₄, or CCl₄, a fluorinated gas such as CF₄, SF₆, or NF₃, or O₂ can be used appropriately.

Next, a light emitting layer 5004 is formed. The light emitting layer 5004 includes a layer made from an inorganic fluorescent material, as which a known inorganic fluorescent material can be used.

An inorganic fluorescent material includes a base material and an impurity element which is to be a light-emission center. By changing the impurity element that is contained, light emission of various colors can be obtained.

As the base material used for a light-emitting material, a sulfide, an oxide, or a nitride can be used. As the sulfide, zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), or the like can be used. As the oxide, zinc oxide (ZnO), yttrium oxide (Y₂O₃), or the like can be used. As the nitride, aluminum nitride (AlN), gallium nitride (GaN), indium nitride (InN), or the like can be used. Further, zinc selenide (ZnSe), zinc telluride (ZnTe), or the like can also be used. A ternary mixed crystal such as calcium gallium sulfide (CaGa₂S₄), strontium gallium sulfide (SrGa₂S₄), or barium gallium sulfide (BaGa₂S₄) may also be used.

As a light-emission center of localized type luminescence, manganese (Mn), copper (Cu), samarium (Sm), terbium (Th), erbium (Er), thulium (Tm), europium (Eu), cerium (Ce), praseodymium (Pr), or the like can be used. Note that a halogen element such as fluorine (F) or chlorine (Cl) may be added for charge compensation.

On the other hand, as a light-emission center of donor-acceptor recombination type luminescence, a light-emitting material containing a first impurity element which forms a donor level and a second impurity element which forms an acceptor level can be used. As the first impurity element, fluorine (F), chlorine (Cl), aluminum (Al), or the like can be used. As the second impurity element, copper (Cu), silver (Ag), or the like can be used.

Note that the concentration of such an impurity element is 0.01 to 10 atom % with respect to the base material, and the concentration is preferably 0.05 to 5 atom %.

Further, the light emitting layer 5004 is not necessarily a single layer made from an inorganic fluorescent material, and for example, a stacked-layer of a layer which functions as a carrier transporting layer and the layer of the inorganic fluorescent material may be employed. Specifically, a p-type semiconductor, an n-type semiconductor, or the like may be stacked.

As a manufacturing method of the light emitting layer 5004 including at least the layer made from the inorganic fluorescent material, the following can be used: a vacuum evaporation method such as a resistance heating evaporation method or an electron beam evaporation (EB evaporation) method; a physical vapor deposition method (PVD) such as sputtering; a chemical vapor deposition method (CVD) such as a metal organic CVD method or a low-pressure hydride transport CVD method; an atomic layer epitaxy method (ALE); or the like.

The thickness of the light emitting layer 5004 including at least the layer made from the inorganic fluorescent material is equal to or more than 1 nm and equal to or less than 1000 nm, and the thickness is preferably equal to or more than 10 nm and equal to or less than 500 nm.

In order to obtain a film of an inorganic fluorescent material with a desired crystal state which is superior in the luminous efficiency, the formation is performed while heating the substrate at 100 to 1200° C., preferably 100 to 800° C. For example, when a film of zinc sulfide is formed by sputtering, the film formation is preferably performed while heating the substrate at 500° C.

Further, as a microfabrication method of the light emitting layer 5004 into a desired shape, conventional photolithography in which a pattern is formed using a photoresist over a light emitting layer and an unnecessary portion of the light emitting layer is removed by etching, or lift-off in which a reversed pattern is formed using a photoresist, a light emitting layer is formed over the reversed pattern, and an unnecessary portion of the light emitting layer over the photoresist is removed while the photoresist is removed can be used.

After the light emitting layer 5004 including the layer made from the inorganic fluorescent material is thus stacked over the first electrode layer 5002, thermal treatment at a high temperature of 300 to 1500° C., preferably 450 to 1200° C. is performed so that a crystal defect existing in the light emitting layer is repaired and crystal growth is promoted, thereby improving luminous efficiency.

Thermal treatment for crystallization may be performed by using a heating furnace, laser irradiation, irradiation with light emitted from a lamp (also called lamp annealing), or the like. As a heating method, an RTA method such as a GRTA (Gas Rapid Thermal Anneal) method or an LRTA (Lamp Rapid Thermal Anneal) method may be used.

Next, an insulating layer 5003 which functions as a partition wall is formed over the light emitting layer 5004. The insulating layer 5003 which functions as a partition wall can be formed of the following: silicon oxide, silicon nitride, silicon oxynitride, silicon nitride oxide, aluminum nitride (AlN), aluminum oxynitride (AlON), aluminum nitride oxide (AlNO) in which the content of nitrogen is larger than that of oxygen, aluminum oxide, diamond like carbon (DLC), nitrogen-containing carbon (CN), PSG (phosphorus glass), BPSG (boron-phosphorus glass), alumina, or a material selected from other materials containing an inorganic insulating material.

For forming the insulating layer 5003 which functions as a partition wall, dipping, spray coating, a doctor knife, a roll coater, a curtain coater, a knife coater, CVD, a vapor deposition method, or the like can be adopted. The insulating layer 5003 which functions as a partition wall may be formed by a droplet discharge method. In the case of using the droplet discharge method, a material liquid can be saved. Further, a method for transferring or drawing a pattern similarly to the droplet discharge method, such as a printing method (a method for forming a pattern such as screen printing or offset printing) or the like can also be used.

Next, as shown in FIG. 1B, openings are formed in the insulating layer 5003 which functions as a partition wall. The insulating layer 5003 which functions as a partition wall is etched in a pixel portion. Further, as shown in FIG. 6A, it is necessary to perform etching in a large area in the external terminal connection region 202b where the first electrode layer 5002 is connected to a connection terminal, and the like.

The etching can be performed by using a parallel plate RIE apparatus or an ICP etching apparatus. Note that etching time may be determined so that the wiring layer and the first electrode are over-etched. Due to such an etching condition where the wiring layer and the first electrode are over-etched, variation in thickness in the substrate and variation in etching rate can be reduced. In this manner, an opening is formed in the external terminal connection region 202b.

Described in this embodiment mode is the case where the insulating layer 5003 which functions as a partition wall is etched by using the mask in which the predetermined openings are provided in the external terminal connection region 202b and a pixel region 206; however the present invention is not limited thereto. For example, in the opening in the connection region which has a large area, the amount of etching is large. Such an opening with a large area may be formed by etching a plurality of times. Further, in the case of forming an opening which is deeper than the other openings, etching may be performed a plurality of times, similarly.

Next, a second electrode layer 5005 is formed over the light emitting layer 5004. The second electrode layer 5005 is in contact with a source or drain electrode layer of a TFT which is formed later.

A conductive film used as the second electrode layer 5005 (also called a pixel electrode layer) over the light emitting layer 5004 may be formed of an element selected from tantalum (Ta), tungsten (W), titanium (Ti), molybdenum (Mo), aluminum (Al), copper (Cu), chromium (Cr), and neodymium (Nb), or an alloy material or a compound material containing the element as its main component. Further, a semiconductor film typified by a polycrystalline silicon film which is doped with an impurity element such as phosphorus, or an AgPdCu alloy may also be used.

Further, the present invention is not limited to a single layer structure, and a two-layer or a three-layer structure may also be used.

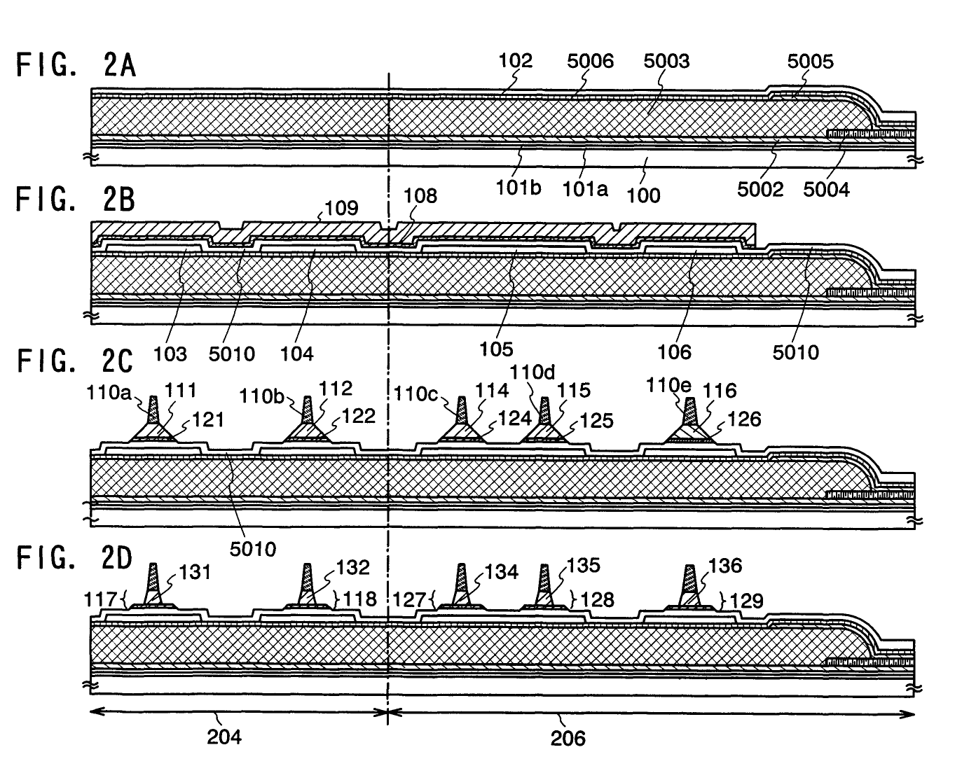

In this embodiment mode, tungsten (W) is stacked with a thickness of 370 nm as the conductive film. Then, a resist mask is formed by photolithography, so that the second electrode layer 5005 is formed (FIG. 2A).

Etching can be performed to be a desired tapered shape by using an ICP (Inductively Coupled Plasma) etching method and appropriately controlling the etching condition (e.g., the amount of electric power applied to a coiled electrode layer, the amount of electric power applied to an electrode layer on the substrate side, the electrode temperature on the substrate side, or the like). As an etching gas, a chlorinated gas such as Cl₂, BCl₃, SiCl₄, or CCl₄, a fluorinated gas such as CF₄, SF₆, or NF₃, or O₂ can be used appropriately.

Next, a first interlayer insulating layer 5006 is formed.

The first interlayer insulating layer 5006 can be formed of the following: silicon oxide, silicon nitride, silicon oxynitride, silicon nitride oxide, aluminum nitride (AlN), aluminum oxynitride (AlON), aluminum nitride oxide (AlNO) in which the content of nitrogen is larger than that of oxygen, aluminum oxide, diamond like carbon (DLC), nitrogen-containing carbon (CN), PSG (phosphorus glass), BPSG (boron-phosphorus glass), alumina, or a material selected from other materials containing an inorganic insulating material.

For forming the first interlayer insulating layer 5006, dipping, spray coating, a doctor knife, a roll coater, a curtain coater, a knife coater, CVD, a vapor deposition method, or the like can be adopted. The first interlayer insulating layer 5006 may be formed by a droplet discharge method. In the case of using the droplet discharge method, a material liquid can be saved. Further, a method for transferring or drawing a pattern similarly to the droplet discharge method, such as a printing method (a method for forming a pattern such as screen printing or offset printing) or the like can be used as well.

Next, as shown in FIGS. 1B and 6A, openings are formed in the first interlayer insulating layer 5006. It is necessary to perform etching in a large area in a connection region (not shown), a wiring region 203, the external terminal connection region 202b, and the like. On the other hand, in the pixel region 206, an opening area is much smaller and minute compared with each opening area in the connection region and the like. Therefore, by providing both a photolithography step for forming the opening in the pixel region and a photolithography step for forming the opening in the connection region, a margin of an etching condition can be widened. Consequently, a yield can be improved. Further, due to the wide margin of the etching condition, a contact hole in the pixel region can be formed with high precision.

Specifically, large area openings are formed in the first interlayer insulating layer 5006 provided partially in the connection region, a wiring region 203, the external terminal connection region 202b, and a peripheral driver circuit region 204. Therefore, a mask is formed to cover the first interlayer insulating layer 5006 in the pixel region 206, a part of the connection region, and a part of the peripheral driver circuit region 204. Etching can be performed by using a parallel plate RIE apparatus or an ICP etching apparatus. Note that etching time may be determined so that the second electrode and the insulating layer which functions as a partition wall are over-etched. Due to such an etching condition where the second electrode and the insulating layer which functions as a partition wall are over-etched, variation in thickness in the substrate and variation in etching rate can be reduced. In this manner, each opening is formed in the external terminal connection region 202b.

Next, a semiconductor film is formed over the first interlayer insulating layer 5006 (FIG. 2B). The semiconductor film may be formed by a known method (e.g., sputtering, LPCVD, or plasma CVD) with a thickness of 25 to 200 nm (preferably 30 to 150 nm). In this embodiment mode, it is preferable to use a crystalline semiconductor film formed by crystallizing an amorphous semiconductor film by laser irradiation.

As a material for forming the semiconductor film, the following can be used: an amorphous semiconductor (hereinafter also called an “AS”) manufactured by sputtering or a vapor deposition method using a semiconductor material gas typified by silane or germane; a polycrystalline semiconductor formed by crystallizing the amorphous semiconductor by using light energy or heat energy; a semi-amorphous (also called microcrystal) semiconductor (hereinafter also called a “SAS”); and the like.

An SAS is a semiconductor having an intermediate structure between amorphous and crystalline (including single crystalline and polycrystalline) structures and having a third state which is stable in free energy. Moreover, an SAS contains a crystalline region having a short-range order and lattice distortion. A region of crystals having a diameter of 0.5 to 20 nm is observed in at least a portion of a film thereof. In the case of containing silicon as a main component, Raman spectrum is shifted toward lower wave numbers than 520 cm⁻¹. The diffraction peaks of (111) and (220), which are considered to be derived from a silicon crystal lattice, are observed by X-ray diffraction.

Hydrogen or halogen is contained at at least 1 atom % or more in order to terminate dangling bonds.

An SAS is formed by depositing a gas containing silicon by glow discharge decomposition (plasma CVD). The gas containing silicon is typically SiH₄, or Si₂H₆, SiH₂Cl₂, SiHCl₃, SiCl₄, SiF₄, or the like. Further, F₂ or GeF₄ may be mixed. The gas containing silicon may be diluted with H₂ or a mixed gas of H₂ and one or a plurality of rare gas elements of He, Ar, Kr, and Ne. The dilution ratio is 2 to 1000 times, the pressure is approximately 0.1 to 133 Pa, and the power supply frequency is 1 to 120 MHz, preferably 13 to 60 MHz. The substrate heating temperature is preferably equal to or less than 300° C., and it is possible for manufacturing that the substrate heating temperature is 100 to 200° C.

Here, it is preferable that an impurity of atmospheric components such as oxygen, nitrogen, and carbon as an impurity element contained in forming the film be equal to or less than 1×10²⁰ cm⁻³. In particular, oxygen concentration is preferably equal to or less than 5×10¹⁹ cm⁻³ or less, more preferably equal to or less than 1×10¹⁹ cm⁻³. Further, by mixing a rare gas element such as helium, argon, krypton, or neon, the lattice distortion is increased and the stability is enhanced, so that a favorable SAS can be obtained. Further, as the semiconductor film, a stacked-layer of an SAS layer formed by a hydrogen-based gas over an SAS layer formed by a fluorine-based gas may be used as well.

A typical amorphous semiconductor is hydrogenated amorphous silicon, and a typical crystalline semiconductor is polysilicon or the like. Polysilicon (polycrystalline silicon) includes so-called high-temperature polysilicon formed using polysilicon as a main material at a processing temperature of equal to or more than 800° C., so-called low-temperature polysilicon formed using polysilicon as a main material at a processing temperature of equal to or less than 600° C., polysilicon crystallized by adding an element which promotes crystallization, and the like. It is needless to say that a semi-amorphous semiconductor or a semiconductor containing a crystal phase partially in the film may also be used as described above.

In the case of using a crystalline semiconductor film as the semiconductor film, the crystalline semiconductor film may be formed by any known method (e.g., a laser crystallization method, a thermal crystallization method, or a thermal crystallization method using an element such as nickel which promotes crystallization). Further, a microcrystalline semiconductor which is an SAS may be crystallized by laser irradiation to enhance crystallinity. In the case where an element which promotes crystallization is not used, the amorphous semiconductor film is heated for one hour in a nitrogen atmosphere at 500° C. to release hydrogen until the hydrogen concentration becomes equal to or less than 1×10²⁰ atoms/cm³ before irradiating the amorphous semiconductor film with laser light. This is because if the amorphous semiconductor film contains a large amount of hydrogen, the amorphous semiconductor film would be broken by laser light irradiation.

A method for introducing a metal element into the amorphous semiconductor film is not particularly limited as long as the metal element can exist in a surface or inside the amorphous semiconductor film. For example, sputtering, CVD, plasma treatment (including plasma CVD), an adsorption method, or a method of applying a solution of metal salt can be used. Out of these, the method of using a solution is easy and advantageous in that the concentration of the metal element can be easily controlled. At this time, it is preferable to form an oxide film by UV light irradiation in an oxygen atmosphere, a thermal oxidation method, treatment by using ozone water containing hydroxyl radicals or using hydrogen peroxide, or the like, in order to improve surface wettability of the amorphous semiconductor film to diffuse the aqueous solution over the entire surface of the amorphous semiconductor film.

By using a solid state laser capable of continuous oscillation and irradiating the amorphous semiconductor film with laser light of a second to fourth harmonic thereof, large grain crystals can be obtained. Typically, second (532 nm) or third (355 nm) harmonic of an Nd:YVO₄ laser (fundamental wave is 1064 nm) is preferably used. Specifically, laser light emitted from a continuous-wave YVO₄ laser is converted into a harmonic by using a non-linear optical element, thereby obtaining laser light of output at at least several W. Then, the laser light is preferably shaped into a rectangular or elliptical shape on an irradiated surface by an optical system, for the irradiation of the semiconductor film. The power density at this time is required to be approximately 0.001 to 100 MW/cm² (preferably 0.1 to 10 MW/cm²). In addition, the scan rate is set at approximately 0.5 to 2000 cm/sec (preferably 10 to 200 cm/sec).

The shape of the laser beam is preferably linear; as a result, throughput can be improved. Further, it is preferable that the semiconductor film be irradiated with the laser beam at an incident angle θ (0°<θ<90°) because laser interference can be prevented.

By relatively scanning such laser and the semiconductor film, laser irradiation can be performed. Further, a marker may be formed in order to overlap beams at high precision or control a position to start or finish laser irradiation. The marker may be formed over the substrate at the same time as the amorphous semiconductor film.

Note that as the laser, a gas laser, a solid-state laser, a copper-vapor laser, a gold-vapor laser, or the like capable of continuous oscillation or pulsed oscillation can be used. The gas laser includes an excimer laser, an Ar laser, a Kr laser, a He—Cd laser, and the like. The solid-state laser includes a YAG laser, a YVO₄ laser, a YLF laser, a YAlO₃ laser, a Y₂O₃ laser, a glass laser, a ruby laser, an alexandrite laser, a Ti:sapphire laser, and the like.

The laser crystallization may also be performed by a pulsed laser at a repetition rate of equal to or more than 0.5 MHz, which is a drastically higher frequency band than a generally used frequency band of several ten to several hundred Hz. It is said that the time between irradiation with pulsed laser light and complete solidification of the semiconductor film is several ten to several hundred nsec. Therefore, by using the above-described frequency band, the semiconductor film can be irradiated with the next pulse of the laser light during the period from melting the semiconductor film by the preceding pulse to completion of solidification of the semiconductor film. Therefore, since a solid-liquid interface can be continuously moved in the semiconductor film, a semiconductor film having crystal grains that have grown continuously in the scanning direction of the laser beam is formed. Specifically, an aggregate of crystal grains having widths of 10 to 30 μm in the scanning direction and widths of approximately 1 to 5 μm in the direction perpendicular to the scanning direction can be formed. By forming single crystal grains extended long along the scanning direction, a semiconductor film which has almost no crystal boundary at least in a channel direction of a thin film transistor can be formed.

Further, the semiconductor film may be irradiated with laser light in an inert gas atmosphere of rare gas, nitrogen, or the like. As a result of this, roughness of a semiconductor surface due to laser light irradiation can be prevented, and variation of a threshold voltage due to variation of an interface state density can be suppressed.

The amorphous semiconductor film may also be crystallized by a combination of thermal treatment and laser light irradiation, or either one of thermal treatment and laser light irradiation may be performed a plurality of times.

In this embodiment mode, an amorphous semiconductor film is formed over the first interlayer insulating layer 5006 and is crystallized to form a crystalline semiconductor film. As the amorphous semiconductor film, amorphous silicon formed using a reaction gas of SiH₄ and H₂ is used.

In this embodiment mode, the first interlayer insulating layer 5006 and the amorphous semiconductor film are continuously formed by changing the reaction gas without breaking the vacuum in the same chamber at the same temperature of 330° C.

After an oxide film formed on the amorphous semiconductor film is removed, an oxide film is formed with a thickness of 1 to 5 nm by UV light irradiation in an oxygen atmosphere, a thermal oxidization method, treatment by ozone water containing hydroxy radicals or hydrogen peroxide solution, or the like.

In this embodiment mode, Ni is used as the element for promoting crystallization. An aqueous solution containing nickel acetate at 10 ppm is applied by a spin coating method.

In this embodiment mode, after thermal treatment is performed by an RTA method at 750° C. for three minutes, the oxide film formed on the semiconductor film is removed and laser irradiation is applied. The amorphous semiconductor film is crystallized by this crystallization treatment to become a crystalline semiconductor film.

In the case of performing crystallization using a metal element, gettering is performed in order to reduce or remove the metal element. In this embodiment mode, the metal element is captured using the amorphous semiconductor film as a gettering sink.

First, an oxide film is formed over a crystalline semiconductor film by UV light irradiation in an oxygen atmosphere, thermal oxidation, treatment with ozone water containing hydroxyl radicals, treatment with hydrogen peroxide, or the like. The oxide film is preferably formed to be thick by thermal treatment. Then, an amorphous semiconductor film is formed with a thickness of 50 nm by plasma CVD (with a condition of 350 W and 35 Pa in this embodiment mode).

After that, thermal treatment is performed at 744° C. for three minutes by an RTA method to reduce or remove the metal element. The thermal treatment may be performed in a nitrogen atmosphere. Then, the amorphous semiconductor film functioning as a gettering sink and an oxide film formed on the amorphous semiconductor film are removed by hydrofluoric acid or the like, thereby a crystalline semiconductor film 102 with the metal element reduced or removed can be obtained (see FIG. 2A). In this embodiment mode, the amorphous semiconductor film functioning as a gettering sink is removed by TMAH (TetraMethyl Ammonium Hydroxide).

The semiconductor film thus obtained may be doped with an impurity element (boron or phosphorus) at a slight amount in order to control a threshold voltage of a thin film transistor. This doping of the impurity element may be performed to the amorphous semiconductor film before crystallization. If the amorphous semiconductor film is doped with the impurity element, the impurity can be activated by later thermal treatment for crystallization. Moreover, a defect and the like generated at the doping can be improved.

Then, the crystalline semiconductor film 102 is processed into a desired shape by using a mask. In this embodiment mode, after removing an oxide film formed on the crystalline semiconductor film 102, an oxide film is formed again. Then, a photo resist as a mask is formed over the crystalline semiconductor film with the oxide film interposed therebetween, and a process using photolithography is performed, thereby semiconductor layers 103 to 106 are formed.

An etching process may be either plasma etching (dry etching) or wet etching. In the case of processing a large-area substrate, plasma etching is preferable. As an etching gas, a fluorine-based gas or a chlorine-based gas such as CF₄, NF₃, Cl₂, or BCl₃ is used, to which an inert gas such as He or Ar may be added as appropriate. In the case of employing an etching process by atmospheric pressure electric discharge, local electric discharge can also be performed, so that a mask layer is not necessarily formed over an entire surface of the substrate.

In this embodiment mode, a conductive layer for forming a wiring layer or an electrode layer, a mask layer for forming a predetermined pattern, or the like may be formed by a method by which a pattern can be selectively formed, such as a droplet discharge method. In a droplet discharge method (also called an inkjet method according to the system thereof), a predetermined pattern (e.g., a conductive layer or an insulating layer) can be formed by selectively discharging (ejecting) droplets of a composition prepared for a specific purpose. At this time, a process for controlling wettability or adhesion may be performed in a region to be formed. Further, a method for transferring or drawing a pattern, for example, a printing method (a method for forming a pattern such as screen printing or offset printing) or the like can be used.

In this embodiment mode, a resin material such as an epoxy resin, an acrylic resin, a phenol resin, a novolac resin, a melamine resin, or a urethane resin is used as a mask. Further, the mask may also be made from an organic material such as benzocyclobutene, parylene, fluorinated arylene ether, or polyimide having a light-transmitting property; a compound material formed by polymerization such as a siloxane polymer or the like; a composition material containing a water-soluble homopolymer and a water-soluble copolymer; or the like. Further, a commercially available resist material containing a photosensitive agent may also be used. For example, it is possible to use a positive resist or a negative resist. When a droplet discharge method is used, the surface tension and the viscosity of any material are appropriately adjusted by controlling the solvent concentration or by adding a surfactant or the like.

The oxide film on each semiconductor layer is removed, and a gate insulating layer 5010 covering the semiconductor layers 103 to 106 is formed. The gate insulating layer 5010 is formed of an insulating film containing silicon with a thickness of 10 to 150 nm by plasma CVD, a sputtering method, or the like.

The gate insulating layer 5010 may be formed of a material such as an oxide material or nitride material of silicon, typified by silicon nitride, silicon oxide, silicon oxynitride, or silicon nitride oxide and may employ either a single layer structure or a stacked-layer structure. Further, the insulating layer may employ a three-layer structure of a silicon nitride film, a silicon oxide film, and a silicon nitride film, or a single layer of a silicon oxynitride film or a two-layer structure. Preferably, a silicon nitride film having a dense film quality is used. Moreover, a thin silicon oxide film may be formed with a thickness of 1 to 100 nm, preferably 1 to 10 nm, and more preferably 2 to 5 nm between the semiconductor layer and the gate insulating layer. The thin silicon oxide film can be formed by oxidizing a surface of the semiconductor region by a GRTA method, an LRTA method, or the like to form a thermal oxide film. Note that a rare gas element such as argon may be added to a reactive gas to be mixed into an insulating film to be formed, in order to form a dense insulating film having less gate leak current at a low film formation temperature. In this embodiment mode, a silicon oxynitride film is formed with a thickness of 115 nm as the gate insulating layer 5010.

Next, a first conductive film 108 having a thickness of 20 to 100 nm and a second conductive film 109 having a thickness of 100 to 400 nm, which serve as a gate electrode layer, are stacked over the gate insulating layer 5010 (see FIG. 2B). The first conductive film 108 and the second conductive film 109 can be formed by a sputtering method, a vapor deposition method, CVD, or the like. The first conductive film 108 and the second conductive film 109 may be formed of an element selected from tantalum (Ta), tungsten (W), titanium (Ti), molybdenum (Mo), aluminum (Al), copper (Cu), chromium (Cr), and neodymium (Nd), or an alloy material or a compound material containing the aforementioned element as a main component. Further, a semiconductor film typified by a polycrystalline silicon film that is doped with an impurity element such as phosphorus or an AgPdCu alloy may be used as each of the first conductive film 108 and the second conductive film 109. Further, the gate electrode layer is not limited to a two-layer structure, and for example, may employ a three-layer structure in which a tungsten film with a thickness of 50 nm as the first conductive film, an alloy film of aluminum and silicon (Al—Si) with a thickness of 500 nm as the second conductive film, and a titanium nitride film with a thickness of 30 nm as the third conductive film are sequentially stacked. In the case of a three-layer structure, tungsten nitride may be used instead of tungsten of the first conductive film; an alloy film of aluminum and titanium (Al—Ti) may be used instead of the alloy film of aluminum and silicon (Al—Si) of the second conductive film; and a titanium film may be used instead of the titanium nitride film of the third conductive film. Further, a single-layer structure may also be employed. In this embodiment mode, tantalum nitride (TaN) is stacked with a thickness of 30 nm as the first conductive film 108 and tungsten (W) is stacked with a thickness of 370 nm as the second conductive film 109.

Then, resist masks 110a to 110e are formed by photolithography, and the first conductive film 108 and the second conductive film 109 are processed into desired shapes, thereby forming first gate electrode layers 121, 122, 124, 125, and 126, and conductive layers 111, 112, 114, 115, and 116 (FIG. 2C).

The first gate electrode layers 121, 122, 124, 125, and 126, and the conductive layers 111, 112, 114, 115, and 116 can be etched to have desired tapered shapes by using an ICP (Inductively Coupled Plasma) etching method and appropriately adjusting an etching condition (e.g., the amount of electric power to be applied to a coil-shaped electrode layer, the amount of electric power to be applied to an electrode layer on a substrate side, or electrode temperature on a substrate side). Further, an angle or the like of each tapered shape can be controlled by each shape of the masks 110a to 110e. As an etching gas, a chlorine-based gas typified by Cl₂, BCl₃, SiCl₄, CCl₄, or the like, a fluorine-based gas typified by CF₄, SF₆, NF₃, or the like, or O₂ can be appropriately used. In this embodiment mode, the second conductive film 109 is etched using an etching gas containing CF₄, Cl₂, and O₂ and then continuously the first conductive film 108 is etched using an etching gas containing CF₄ and Cl₂.

Then, the conductive layers 111, 112, 114, 115, and 116 are processed into desired shapes by using the masks 110a to 110e. At this time, each conductive layer is etched with an etching condition of high selection ratio of the second conductive film 109 which forms each conductive layer with respect to the first conductive film 108 which forms each first gate electrode layer. By this etching, the conductive layers 111, 112, 114, 115, and 116 are etched, thereby forming second gate electrode layers 131, 132, 134, 135, and 136. In this embodiment mode, the second gate electrode layers have tapered shapes of which tapered angles are larger than those of the first gate electrode layers 121, 122, 124, 125, and 126. It is to be noted that a tapered angle is an angle of a side surface with respect to surfaces of each first gate electrode layer, each second gate electrode layer, and each conductive layer. Accordingly, when the tapered angle is increased to 90°, each conductive layer has a perpendicular side. In this embodiment mode, each second gate electrode layer is formed using an etching gas of Cl₂, SF₆, and O₂.

In this embodiment mode, since each first gate electrode layer, each conductive layer, and each second gate electrode layer are formed to have tapered shapes, both of the two gate electrode layers have tapered shapes. However, the present invention is not limited to this and either one of the two gate electrode layers may have a tapered shape while the other has a perpendicular side formed by anisotropic etching. The tapered angle may be different between the stacked gate electrode layers like this embodiment mode, or may be the same. With a tapered shape, coverage with a film to be stacked thereover is improved and a defect is reduced, so that reliability is improved.

Through the above-described steps, a gate electrode layer 117 formed of the first gate electrode layer 121 and the second gate electrode layer 131, and a gate electrode layer 118 formed of the first gate electrode layer 122 and the second gate electrode layer 132 can be formed in a peripheral driver circuit region 204, and a gate electrode layer 127 formed of the first gate electrode layer 124 and the second gate electrode layer 134, a gate electrode layer 128 formed of the first gate electrode layer 125 and the second gate electrode layer 135, and a gate electrode layer 129 formed of the first gate electrode layer 126 and the second gate electrode layer 136 can be formed in the pixel region 206 (FIG. 2D). Although the gate electrode layers are formed by dry etching in this embodiment mode, wet etching may be employed as well.

Due to the etching process for forming the gate electrode layers, the gate insulating layer 5010 may be etched to some extent, thereby the thickness is reduced in some cases (i.e., film reduction).

By forming each gate electrode layer to have a narrow width, a thin film transistor capable of high speed operation can be formed. Two methods for forming the gate electrode layer to have a narrow width in a channel direction are described below.

The first method is as follows: A mask for a gate electrode layer is formed, and the mask is slimed in a width direction by etching, ashing, or the like to form a mask with a narrower width. By using the mask formed in advance with a narrower width, each gate electrode layer can also be formed in a shape with a narrower width.

The second method is as follows: A normal mask is formed, and then a gate electrode layer is formed using the mask; then, the obtained gate electrode layer is etched in the side in a width direction to be slimed. Accordingly, a gate electrode layer with a narrower width can be formed. Through the above-described process, a thin film transistor with a short channel length can be formed, which can realize a thin film transistor capable of high speed operation.

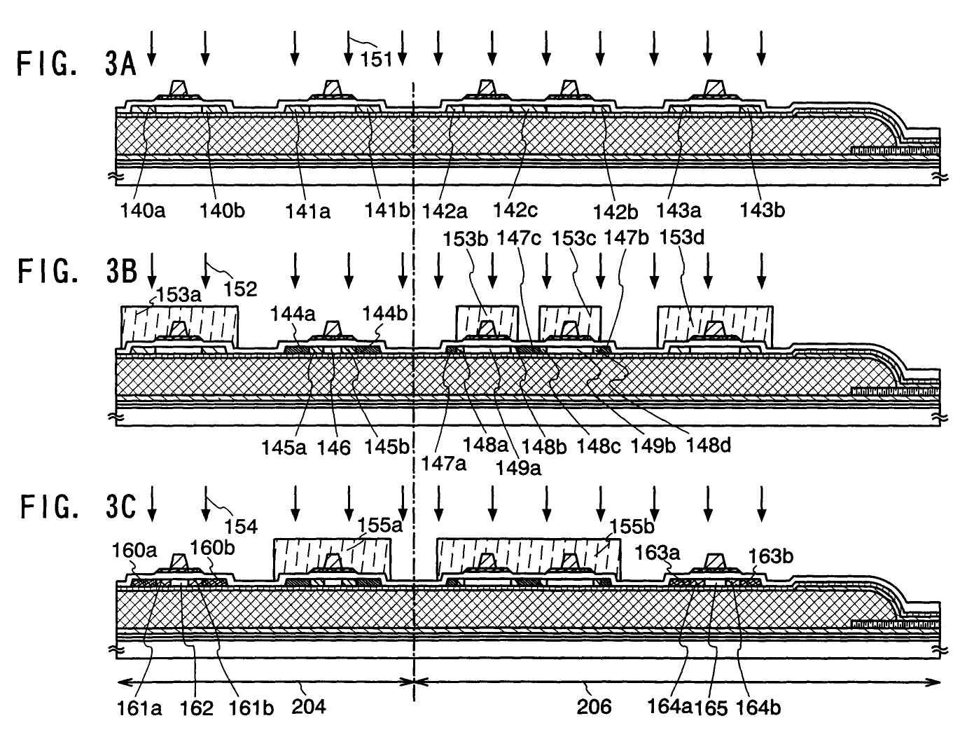

Next, an impurity element 151 which imparts n-type conductivity is added using the gate electrode layers 117, 118, 127, 128, and 129 as masks, thereby forming first n-type impurity regions 140a, 140b, 141a, 141b, 142a, 142b, 142c, 143a, and 143b (see FIG. 3A). In this embodiment mode, doping is performed by using phosphine (PH₃) as a doping gas containing an impurity element (PH₃ is diluted with hydrogen (H₂) in the doping gas, and the composition ratio of PH₃ is 5% in the gas) at a gas flow rate of 80 sccm, with a beam current of 54 μA/cm, with an acceleration voltage of 50 kV, and at a dosage of 7.0×10¹³ ions/cm². Here, doping is performed so that the impurity element which imparts n-type conductivity is contained at a concentration of about 1×10¹⁷ to 5×10¹⁸ cm³ in each of the first n-type impurity regions 140a, 140b, 141a, 141b, 142a, 142b, 142c, 143a, and 143b. In this embodiment mode, phosphorus (P) is used as the impurity element which imparts n-type conductivity.

In this embodiment mode, each impurity region where each gate electrode layer is overlapped with the gate insulating layer interposed therebetween is referred to as a Lov region while each impurity region where each gate electrode layer is not overlapped with the gate insulating layer interposed therebetween is referred to as a Loff region. In FIGS. 3A to 3C, the impurity regions are shown by hatching and blank spaces. This does not mean that the blank spaces are not doped with the impurity element, but shows that the concentration distribution of the impurity element in this region depends on the mask and the doping condition. Note that this is the same in the other drawings of this specification.

Then, masks 153a, 153b, 153c, and 153d which cover the semiconductor layer 103, a part of the semiconductor layer 105, and the semiconductor layer 106 are formed. By using the masks 153a, 153b, 153c, and 153d, and the second gate electrode layer 132 as masks, an impurity element 152 which imparts n-type conductivity is added, thereby forming second n-type impurity regions 144a and 144b, third n-type impurity regions 145a and 145b, second n-type impurity regions 147a, 147b, and 147c, and third n-type impurity regions 148a, 148b, 148c, and 148d. In this embodiment mode, doping is performed by using phosphine (PH₃) as a doping gas containing an impurity element (PH₃ is diluted with hydrogen (H₂) in the doping gas, and the composition ratio of PH₃ is 5% in the gas) at a gas flow rate of 80 sccm, with a beam current of 540 μA/cm, with an acceleration voltage of 70 kV, and at a dosage of 5.0×10¹⁵ ions/cm². Here, doping is performed so that the impurity element which imparts n-type conductivity is contained at a concentration of about 5×10¹⁹ to 5×10²⁰ cm³ in each of the second n-type impurity regions 144a and 144b. The third n-type impurity regions 145a and 145b are formed so as to contain the impurity element which imparts n-type conductivity at approximately the same concentration as or at a little higher concentration than the third n-type impurity regions 148a, 148b, 148c, and 148d. Further, a channel formation region 146 is formed in the semiconductor layer 104, and channel formation regions 149a and 149b are formed in the semiconductor layer 105 (see FIG. 3B).

The second n-type impurity regions 144a, 144b, 147a, 147b, and 147c are high-concentration n-type impurity regions each of which functions as a source or a drain. On the other hand, the third n-type impurity regions 145a, 145b, 148a, 148b, 148c, and 148d are low-concentration impurity regions which function as LDD (Lightly Doped Drain) regions. The n-type impurity regions 145a and 145b, which are covered with the first gate electrode layer 122 with the gate insulating layer 5010 interposed therebetween, are Lov regions, and can alleviate an electric field around each drain and suppress degradation of an on current due to hot carriers. As a result of this, a thin film transistor capable of high speed operation can be formed. On the other hand, the third n-type impurity regions 148a to 148d are formed in Loff regions which are not covered with the gate electrode layers 127 and 128; therefore an off current can be reduced. Accordingly, a semiconductor device with high reliability and low power consumption can be manufactured.

Then, the masks 153a to 153d are removed and masks 155a and 155b to cover the semiconductor layers 103 and 105 are formed. An impurity element 154 which imparts p-type conductivity is added using the masks 155a and 155b, and the gate electrode layers 117 and 129 as masks, thereby forming first p-type impurity regions 160a, 160b, 163a, 163b, and the second p-type impurity regions 161a, 161b, 164a, and 164b. In this embodiment mode, boron (B) is used as the impurity element, and therefore, doping is performed by using diborane (B₂H₆) as a doping gas containing the impurity element (B₂H₆ is diluted with hydrogen (H₂) in the doping gas, and the composition ratio of B₂H₆ is 15% in the gas) at a gas flow rate of 70 sccm, with a beam current of 180 μA/cm, with an acceleration voltage of 80 kV, and at a dosage of 2.0×10¹⁵ ions/cm². Here, doping is performed so that the impurity element which imparts p-type conductivity is contained at a concentration of about 1×10²⁰ to 5×10²¹ cm³ in each of the first p-type impurity regions 160a, 160b, 163a, 163b, and second p-type impurity regions 161a, 161b, 164a, and 164b. In this embodiment mode, the second p-type impurity regions 161a, 161b, 164a, and 164b are formed in accordance with the shapes of the gate electrode layers 117 and 129, and are formed such that the concentration of an impurity element is less than that of each of the first p-type impurity regions 160a, 160b, 163a, and 163b in a self-aligned manner. Further, a channel formation region 162 is formed in the semiconductor layer 103 and a channel formation region 165 is formed in the semiconductor layer 106 (see FIG. 3C).

The second n-type impurity regions 144a, 144b, 147a, 147b, and 147c are high-concentration n-type impurity regions each of which functions as a source or a drain. On the other hand, the second p-type impurity regions 161a, 161b, 164a, and 164b are low-concentration impurity regions which function as LDD (Lightly Doped Drain) regions. The second p-type impurity regions 161a, 161b, 164a, and 164b, which are covered with the first gate electrode layer 121 or 126 with the gate insulating layer 5010 interposed therebetween, are Lov regions, and can alleviate an electric field around each drain and suppress degradation of an on current due to hot carriers.

The masks 155a and 155b are removed by O₂ ashing or using a resist stripping solution. After that, an insulating film, namely a sidewall may be formed so as to cover a side surface of each gate electrode layer. The sidewall may be formed of an insulating film containing silicon by a plasma CD method and a low-pressure CVD (LPCVD) method.

In order to activate the impurity element, thermal treatment, strong light irradiation, or laser light irradiation may be performed. At the same time as activation, plasma damage to the gate insulating layer and to an interface between the gate insulating layer and the semiconductor layer can be recovered.

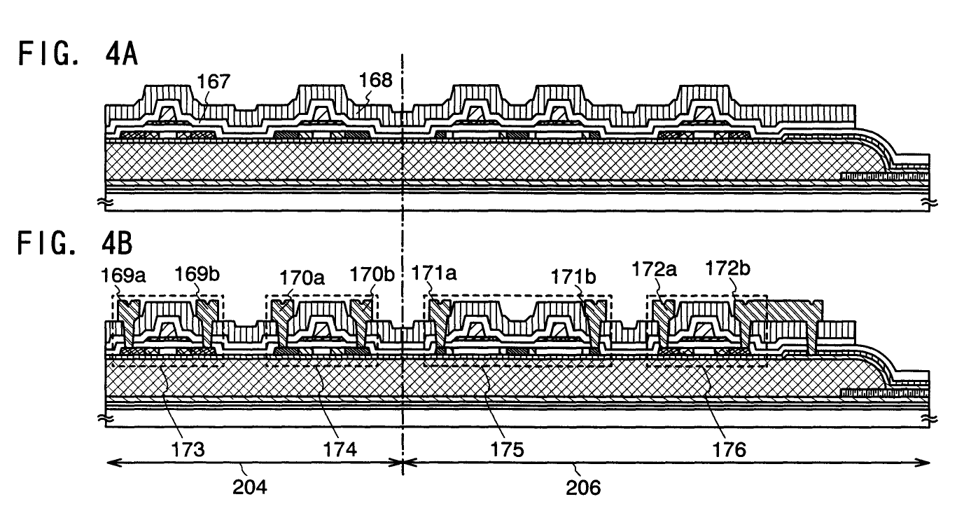

Next, an interlayer insulating layer which covers the gate insulating layer and the gate electrode layer is formed. In this embodiment mode, a stacked-layer structure of insulating films 167 and 168 is employed (see FIG. 4A). A silicon nitride oxide film is formed as the insulating film 167 with a thickness of 100 nm and an oxynitride insulating film is formed as the insulating film 168 with a thickness of 900 nm to form the stacked-layer structure. Further, a three-layer structure may be employed by forming a silicon oxynitride film with a thickness of 30 nm, a silicon nitride oxide film with a thickness of 140 nm, and a silicon oxynitride film with a thickness of 800 nm so as to cover the gate electrode layer and the gate insulating layer. In this embodiment mode, the insulating films 167 and 168 are continuously formed by plasma CVD similarly to the base film. The insulating films 167 and 168 are not limited to the above materials and may be a silicon nitride film, a silicon nitride oxide film, a silicon oxynitride film, or a silicon oxide film formed by sputtering or plasma CVD. Further, a single layer structure or a stacked-layer structure of three or more layers using another insulating film containing silicon may be employed as well.

Further, thermal treatment is performed in a nitrogen atmosphere at 300 to 550° C. for 1 to 12 hours, thereby a step of hydrogenating the semiconductor layer is performed. Preferably, this step is performed at 400 to 500° C. According to this step, dangling bonds in the semiconductor layer can be terminated by hydrogen contained in the insulating film 167 which forms the interlayer insulating layer. In this embodiment mode, thermal treatment is performed at 410° C. for one hour.

Each of the insulating films 167 and 168 may also be formed of a material selected from aluminum nitride (AlN), aluminum oxynitride (AlON), aluminum nitride oxide (AlNO) in which the content of nitrogen is larger than that of oxygen, aluminum oxide, diamond-like carbon (DLC), carbon nitride (CN), and other materials containing an inorganic insulating material.

Further, a siloxane resin may also be used. It is to be noted that a siloxane resin corresponds to a resin containing a Si—O—Si bond. Siloxane has a skeleton structure of a bond of silicon (Si) and oxygen (O). As a substituent, an organic group containing at least hydrogen (e.g., an alkyl group or aromatic hydrocarbon) or a fluoro group may be used. Further, an organic group containing at least hydrogen and a fluoro group may also be used as a substituent. Alternatively, an organic insulating material may be used such as polyimide, acrylic, polyamide, polyimide amide, resist, benzocyclobutene, or polysilazane. A coated film with good planarity formed by a coating method may be used as well.

Then, using a resist mask, contact holes (openings) reaching the semiconductor layer are formed in the insulating films 167 and 168 and the gate insulating layer 5010, and contact holes (openings) reaching the second electrode layer 5005 are formed in the insulating films 167 and 168, the gate insulating layer 5010, and the first interlayer insulating layer 5006. Etching may be performed once or a plurality of times depending on a selection ratio of a material to be used. In this embodiment mode, first etching is performed with a condition that a selection ratio of the silicon oxynitride film which is the insulating film 168 to the silicon nitride oxide film which is the insulating film 167, the gate insulating layer 5010, and the first interlayer insulating layer 5006 can be obtained, thereby the insulating film 168 is partially removed.

Then, by second etching, the insulating film 167 and the gate insulating layer 5010 are partially removed so that openings reaching the first p-type impurity regions 160a, 160b, 163a, and 163b and the second n-type impurity regions 144a, 144b, 147a, and 147b each of which is source or drain region are formed.

In addition, by the second etching, the insulating film 167 and the first interlayer insulating layer 5006 are partially removed so that an opening reaching the second electrode is formed.

In this embodiment mode, the first etching is performed by wet etching while the second etching is performed by dry etching. A hydrofluoric acid-based solution such as a mixed solution of ammonium hydrogen fluoride and ammonium fluoride may be used as an etchant of wet etching. As an etching gas, a chlorine-based gas typified by Cl₂, BCl₃, SiCl₄, CCl₄, or the like, a fluorine-based gas typified by CF₄, SF₆, NF₃, or the like, or O₂ can be appropriately used. Further, an inert gas may be added to the etching gas. As the inert element to be added, one or a plurality of elements selected from He, Ne, Ar, Kr, and Xe can be used.

A conductive film is formed so as to cover the openings, and the conductive film is etched to form source or drain electrode layers 169a, 169b, 170a, 170b, 171a, 171b, 172a, and 172b which are electrically connected to respective parts of the source or drain regions. The source or drain electrode layer 172b is also electrically connected to the second electrode.

The source or drain electrode layer can be formed by forming the conductive film by PVD, CVD, a vapor deposition method, or the like and then etching into desired shapes. Alternatively, a conductive layer can be selectively formed in a predetermined position by a droplet discharge method, a printing method, an electroplating method, or the like. Further alternatively, a reflow method or a damascene method may be used. Each of the source or drain electrode layers is formed of a metal such as Ag, Au, Cu, Ni, Pt, Pd, Ir, Rh, W, Al, Ta, Mo, Cd, Zn, Fe, Ti, Zr, Ba, or the like; Si or Ge; or an alloy or a nitride thereof. Further, a stacked-layer structure of any of them may be employed. In this embodiment mode, a stacked-layer structure is formed by stacking titanium (Ti) with a thickness of 60 nm, a titanium nitride film with a thickness of 40 nm, aluminum with a thickness of 700 nm, and titanium (Ti) with a thickness of 200 nm, and then processed into a desired shape.

Through the above-described steps, an active matrix substrate can be manufactured in which a p-channel thin film transistor 173 having a p-type impurity region in a Lov region and an n-channel thin film transistor 174 having an n-channel impurity region in a Lov region are formed in the peripheral driver circuit region 204, and a multi-channel n-channel thin film transistor 175 having an n-type impurity region in a Loff region and a p-channel thin film transistor 176 having a p-type impurity region in a Lov region are formed in the pixel region 206 (see FIG. 4B).

The present invention is not limited to this embodiment mode, and each thin film transistor may employ a single gate structure in which one channel formation region is formed, a double-gate structure in which two channel formation regions are formed, or a triple-gate structure in which three channel formation regions are formed.

Note that the present invention is not limited to the manufacturing method of a thin film transistor described in this embodiment mode, but can also be applied to a top-gate type (planar type), a bottom-gate type (inverted staggered type), a dual-gate type in which two gate electrode layers are arranged above and below a channel region with gate insulating films interposed therebetween, or other structures.

Next, a protection film 5019 which covers the pixel region 206 and the peripheral driver circuit region 204 is formed. In this embodiment mode, the protection film 5019 may employ either a single layer structure or a stacked-layer structure. For example, a stacked-layer structure of a silicon nitride oxide film with a thickness of 100 nm and an oxynitride insulating film with a thickness of 900 nm may be employed. Further, a three-layer structure may be employed.

In this embodiment mode, the protection film 5019 is continuously formed by plasma CVD similarly to the base film. The protection film 5019 is not limited to the above materials and may be a silicon nitride film, a silicon nitride oxide film, a silicon oxynitride film, or a silicon oxide film formed by sputtering or plasma CVD. Further, a single layer structure or a stacked-layer structure of three or more layers using another insulating film containing silicon may be employed as well.

The protection film 5019 may also be formed of a material selected from aluminum nitride (AlN), aluminum oxynitride (AlON), aluminum nitride oxide (AlNO) in which the content of nitrogen is larger than that of oxygen, aluminum oxide, diamond-like carbon (DLC), a carbon nitride film (CN), and other materials containing an inorganic insulating material.

Further, a siloxane resin may also be used. It is to be noted that a siloxane resin corresponds to a resin containing a Si—O—Si bond. Siloxane has a skeleton structure of a bond of silicon (Si) and oxygen (O). As a substituent, an organic group containing at least hydrogen (e.g., an alkyl group or aromatic hydrocarbon) or a fluoro group may be used. Further, an organic group containing at least hydrogen and a fluoro group may also be used as a substituent. Alternatively, an organic insulating material may be used such as polyimide, acrylic, polyamide, polyimide amide, resist, benzocyclobutene, or polysilazane. A coated film with good planarity formed by a coating method may be used as well.

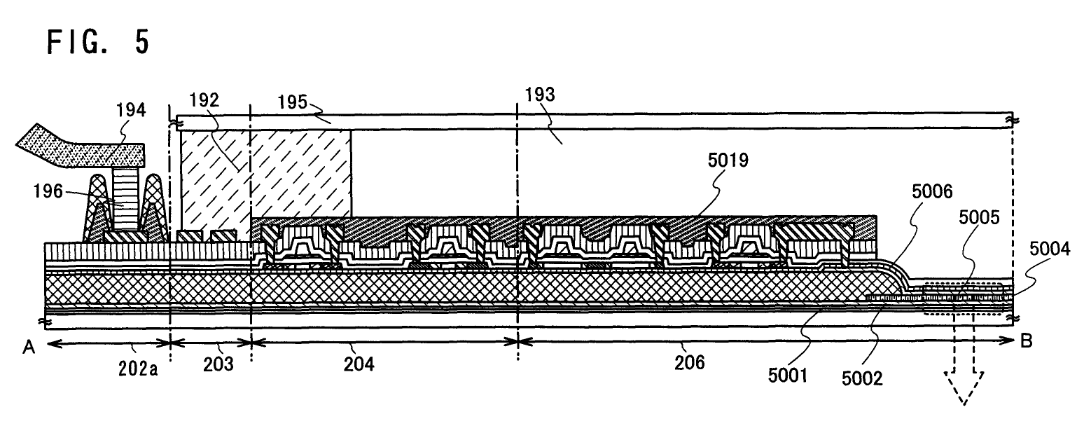

Next, the protection film 5019 is etched using a resist mask provided with a predetermined opening in the external terminal connection region 202a (FIG. 5).

After that, a sealing substrate 195 is attached thereto using a sealing material 192. Further, a space 193 is filled with filler. As the filler, an inert gas (e.g., nitrogen or argon) may be used, or the space may be filled with a sealing material.

As the sealing material, an epoxy resin is preferably used. More preferably, such a material is a material through which moisture and oxygen do not penetrate as much as possible. As the sealing substrate 195, as well as a glass substrate or a quartz substrate, a plastic substrate made from FRP (Fiberglass-Reinforced Plastic), PVF (PolyVinyl Floride), mylar (registered trademark), polyester, acrylic, or the like can be used.

Through the above-described steps, a light emitting device including a TFT and an inorganic EL element of the present invention can be manufactured.

Note that the TFT can also be arranged so as to overlap the first electrode or the second electrode in a thickness direction of a light emitting element (see FIG. 6B). By thus arranging, element area can be reduced.

The light emitting device of the present invention can be applied to an active matrix light emitting device since the thin film transistor (TFT) and the inorganic EL element are included.

Further, since defect increase due to hydrogen elimination from amorphous silicon or polysilicon used in the thin film transistor does not occur, an active matrix inorganic EL display can be manufactured without damaging the TFT properties.

Further, even a low-melting-point material such as aluminum or a low-heat-resistance organic material can be used for the TFT of the inorganic EL display. That is, the range of usable materials is increased.

This embodiment mode can be combined with another embodiment mode as appropriate.

### Embodiment Mode 2

This embodiment mode describes an electronic apparatus including the light emitting device described in Embodiment Mode 1. Each electronic apparatus described in this embodiment mode includes the light emitting device described in Embodiment Mode 1. Thus, an electronic apparatus including an active matrix inorganic EL display including TFTs with good properties can be provided. Further, even in the case of a large-screen display or a high-definition display where the number of pixels is large, an electronic apparatus including an active matrix display portion which can display an image at a high luminance compared with a passive matrix display can be provided.

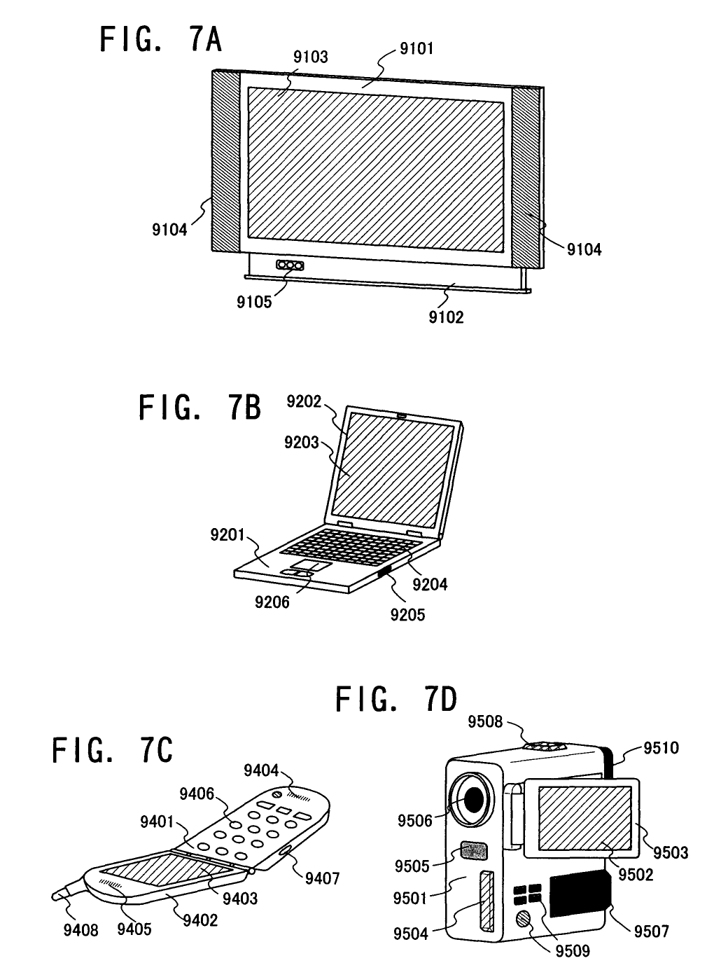

As examples of the electronic apparatus to which the present invention is applied, the following can be given: a camera (e.g., a video camera or a digital camera), a goggle display, a navigation system, a sound reproducing device (e.g., a car audio system or an audio component), a computer, a game machine, a portable information terminal (e.g., a mobile computer, a cellular phone, a mobile game machine, or an electronic book), an image reproducing device having a recording medium (specifically, a device for reproducing a recording medium such as a digital versatile disk (DVD) and having a display for displaying its image), and the like. Specific examples of these electronic devices are shown in FIGS. 7A to 7D.

FIG. 7A shows a television device according to this embodiment mode, which includes a housing 9101, a support base 9102, a display portion 9103, a speaker portion 9104, a video input terminal 9105, and the like. In this television device, the display portion 9103 includes a light emitting device which is similar to that described in Embodiment Mode 1. Thus, a television device including an active matrix inorganic EL display including TFTs with good properties can be provided. Further, even in the case of a large-screen display or a high-definition display where the number of pixels is large, a television device including an active matrix display portion which can display an image at a high luminance compared with a passive matrix display can be provided.

FIG. 7B shows a computer according to this embodiment mode, which includes a main body 9201, a housing 9202, a display portion 9203, a keyboard 9204, an external connection port 9205, a pointing device 9206, and the like. In this computer, the display portion 9203 includes a light emitting device which is similar to that described in Embodiment Mode 1. Thus, a computer including an active matrix inorganic EL display including TFTs with good properties can be provided. Further, even in the case of a large-screen display or a high-definition display where the number of pixels is large, a computer including an active matrix display portion which can display an image at a high luminance compared with a passive matrix display can be provided.

FIG. 7C shows a cellular phone according to this embodiment mode, which includes a main body 9401, a housing 9402, a display portion 9403, an audio input portion 9404, an audio output portion 9405, operation keys 9406, an external connection port 9407, an antenna 9408, and the like. In this cellular phone, the display portion 9403 includes a light emitting device which is similar to that described in Embodiment Mode 1. Thus, a cellular phone including an active matrix inorganic EL display including TFTs with good properties can be provided. Further, even in the case of a large-screen display or a high-definition display where the number of pixels is large, a cellular phone including an active matrix display portion which can display an image at a high luminance compared with a passive matrix display can be provided.

FIG. 7D shows a camera according to this embodiment mode, which includes a main body 9501, a display portion 9502, a housing 9503, an external connection port 9504, a remote control receiving portion 9505, an image receiving portion 9506, a battery 9507, an audio input portion 9508, an operation key 9509, an eyepiece portion 9510, and the like. In this camera, the display portion 9502 includes a light emitting device which is similar to that described in Embodiment Mode 1. Thus, a camera including an active matrix inorganic EL display including TFTs with good properties can be provided. Further, even in the case of a large-screen display or a high-definition display where the number of pixels is large, a camera including an active matrix display portion which can display an image at a high luminance compared with a passive matrix display can be provided.

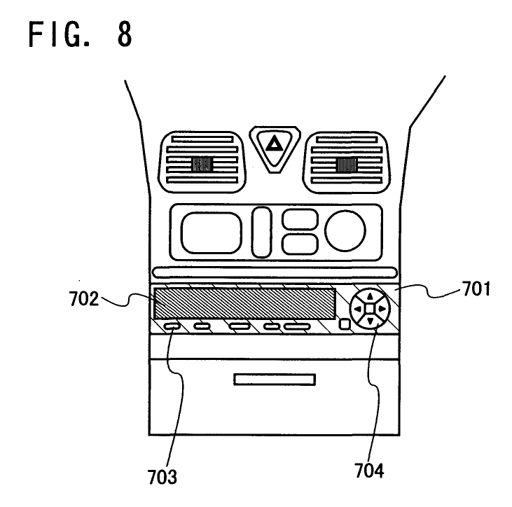

FIG. 8 shows a sound reproducing device according to this embodiment mode, specifically a car audio system, which includes a main body 701, a display portion 702, and operation switches 703 and 704. The display portion 702 includes a light emitting device which is similar to that described in Embodiment Mode 1. Thus, a car audio system including an active matrix inorganic EL display including TFTs with good properties can be provided. Further, even in the case of a large-screen display or a high-definition display where the number of pixels is large, a car audio system including an active matrix display portion which can display an image at a high luminance compared with a passive matrix display can be provided. Further, although this embodiment mode describes an in-car audio system, the present invention may also be used in a portable audio system or an audio system for home use.

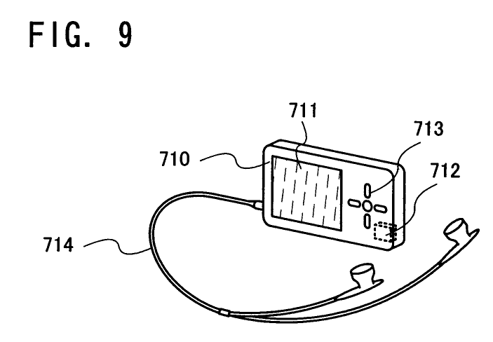

FIG. 9 shows a digital player as one example of that. The digital player shown in FIG. 9 includes a main body 710, a display portion 711, a memory portion 712, an operation portion 713, a pair of earphones 714, and the like. Note that a pair of headphones or a pair of wireless earphones can be used instead of the pair of earphones 714. The display portion 711 includes a light emitting device which is similar to that described in Embodiment Mode 1. Thus, a digital player including an active matrix inorganic EL display including TFTs with good properties can be provided. Further, even in the case of a large-screen display or a high-definition display where the number of pixels is large, a digital player including an active matrix display portion which can display an image at a high luminance compared with a passive matrix display can be provided. As the memory portion 712, a hard disk or a nonvolatile memory is used. For example, a NAND type nonvolatile memory with a recording capacity of 20 to 200 gigabytes (GBs) is used, and the operation portion 713 is operated, thereby an image or a sound (e.g., music) can be recorded and reproduced. In the display portions 704 and 711, power consumption can be suppressed by displaying white characters on a black background. This is particularly effective for a portable audio system.

As described above, the range of application of the light emitting device to which the present invention is applied is very wide. The light emitting device can be applied to electronic apparatuses in various fields. By applying the present invention, an electronic apparatus including an active matrix inorganic EL display including TFTs with good properties can be manufactured.

This application is based on Japanese Patent Application Serial No. 2006-155466 filed in Japan Patent Office on 2, Jun. 2006, the entire contents of which are hereby incorporated by reference.

What is claimed is:

1. A light emitting device comprising:
a first electrode over a substrate;
a light emitting layer provided over the first electrode;
an insulating layer to cover an end portion of the light emitting layer;
a second electrode provided over the light emitting layer; and
a thin film transistor provided over the insulating layer.

2. The light emitting device according to claim 1, wherein the light emitting layer includes an inorganic fluorescent material.

3. An electronic apparatus comprising the light emitting device according to claim 1.

4. A manufacturing method of a light emitting device, comprising the steps of:
forming a first electrode over a substrate;
forming a light emitting layer over the first electrode while heating the substrate provided with the first electrode at a temperature in a range of 100 to 1200° C.;
forming an insulating layer over the light emitting layer;
removing the insulating layer so as to expose the light emitting layer;
forming a second electrode over the light emitting layer; and
forming a thin film transistor over the insulating layer.

5. A manufacturing method of a light emitting device, comprising the steps of:
forming a first electrode over a substrate;
forming a light emitting layer over the first electrode while heating the substrate provided with the first electrode at a temperature in a range of 100 to 800° C.;
forming an insulating layer over the light emitting layer;
removing the insulating layer so as to expose the light emitting layer;
forming a second electrode over the light emitting layer; and
forming a thin film transistor over the insulating layer.

6. A manufacturing method of a light emitting device, comprising the steps of:
forming a first electrode over a substrate;
forming a light emitting layer over the first electrode;
performing thermal treatment at a temperature in a range of 300 to 1500° C. after the light emitting layer is formed;
forming an insulating layer over the light emitting layer;
removing the insulating layer so as to expose the light emitting layer;
forming a second electrode over the light emitting layer; and
forming a thin film transistor over the insulating layer.

7. A manufacturing method of a light emitting device, comprising the steps of:
forming a first electrode over a substrate;
forming a light emitting layer over the first electrode;
performing thermal treatment at a temperature in a range of 450 to 1200° C. after the light emitting layer is formed;
forming an insulating layer over the light emitting layer;
removing the insulating layer so as to expose the light emitting layer;
forming a second electrode over the light emitting layer; and
forming a thin film transistor over the insulating layer.

8. The manufacturing method of the light emitting device, according to claim 4, wherein the light emitting layer includes an inorganic fluorescent material.

9. The manufacturing method of the light emitting device, according to claim 5, wherein the light emitting layer includes an inorganic fluorescent material.

10. The manufacturing method of the light emitting device, according to claim 6, wherein the light emitting layer includes an inorganic fluorescent material.

11. The manufacturing method of the light emitting device, according to claim 7, wherein the light emitting layer includes an inorganic fluorescent material.
